(19) United States
(12) Patent Application Publication
(10) Pub. No.: US 2026/0119753 A1
(43) Pub. Date: Apr. 30, 2026

(54) ITERATIVE DESIGN OF MACHINE ASSEMBLIES USING MACHINE LEARNING MODELS

(71) Applicant: AUTODESK, INC., San Francisco, CA (US)

(72) Inventors: Mohammadmehdi ATAEI, Toronto (CA); Justin Frank MATEJKA, Newmarket (CA); George William FITZMAURICE, Toronto (CA); Hyunmin CHEONG, Toronto (CA); Alexander TESSIER, Toronto (CA)

(21) Appl. No.: 19/255,671

(22) Filed: Jun. 30, 2025

Related U.S. Application Data
(60) Provisional application No. 63/713,032, filed on Oct. 28, 2024.

(51) Int. Cl. G06F 30/27; G06F 30/17

(52) U.S. Cl. CPC G06F 30/27; G06F 30/17

(57) ABSTRACT

One embodiment of a computer-implemented method includes receiving the plurality of design constraints defining properties of a machine assembly, receiving a first selection of a first part in a user interface, the first part selected from a virtual parts inventory, identifying, using a generative machine learning model, a second part from the virtual parts inventory connectable to the first part based on the plurality of design constraints and a second selection of a first location within the first part, and displaying the first part and the second part in a user interface, wherein the first part and the second part comprise a first portion of the machine assembly.

### CROSS-REFERENCE TO RELATED APPLICATIONS

This application claims priority benefit of the United States Provisional Patent Application titled, “TECHNIQUES FOR EXPLORING AND VISUALIZING DIVERSE ASSEMBLY DESIGN PATHWAYS USING GENERATIVE ARTIFICIAL INTELLIGENCE,” filed on Oct. 28, 2024, and having Ser. No. 63/713,032. The subject matter of this related application is hereby incorporated herein by reference.

### BACKGROUND

### Field of the Various Embodiments

Embodiments of the present disclosure relate generally to artificial intelligence (AI), machine learning, and computer-based simulation and, more specifically, to visualization of assembly designs generated using machine learning models.

### Description of the Related Art

Generative artificial intelligence (AI) or machine learning (ML) models can be used to generate machine assemblies. A machine assembly represents a design of a machine or portions of a machine. The design includes one or more parts from a virtual part inventory, or where the parts are also designed using an ML model. The ML model generates a design based on one or more design constraints, such as the direction or type of an input force and the position, direction, or type of an output force. Using a generative machine learning model to generate machine assemblies can result in the ML model generating various designs that may or may not satisfy all of the design constraints provided by a designer or the design preferences of the designer that might not be expressed in the design constraints.

One drawback of using a generative ML model to generate designs for machine assemblies is that a generative ML model often generates a complete design without allowing the designer to provide input at the various stages of the design. For example, an ML model might be equipped to receive various design constraints, then generate a finished design that may or may not comply with one or more of the design constraints. The designs generated by the ML model might include a diverse array of designs with divergent solutions to the design constraints provided by the designer. Additionally, the design constraints provided by the designer to the ML model might not provide the opportunity for the designer to express one or more design preferences.

As the foregoing illustrates, what is needed in the art are more effective techniques for providing designers with tools to create machine assembly designs using generative ML models.

### SUMMARY

One embodiment sets forth a computer-implemented method. The method includes receiving the plurality of design constraints defining properties of a machine assembly, receiving a first selection of a first part in a user interface, the first part selected from a virtual parts inventory, identifying, using a generative machine learning model, a second part from the virtual parts inventory connectable to the first part based on the plurality of design constraints and a second selection of a first location within the first part, displaying the first part and the second part in a user interface, wherein the first part and the second part comprise a first portion of the machine assembly.

Further embodiments provide, among other things, one or more non-transitory computer-readable media and systems configured to implement the method set forth above.

At least one technical advantage of the disclosed techniques relative to the prior art is that the disclosed techniques provide mechanisms to iteratively generate machine assemblies using a generative machine learning (ML) model. In particular, the disclosed techniques provide a mechanism for a designer to interactively and iteratively participate in the design of machine assemblies while relying on an ML model to generate one or more aspects of the design. Iterative generation of machine assemblies allows for generated machine assemblies that more closely align with designer preferences and improved quality as opposed to relying on an ML model to generate completed designs that might not align with designer preferences. Furthermore, the disclosed techniques enable a designer to provide design constraints to the ML model and deliver granular feedback on the direction in which the ML model iterates the design of the machine assembly. Again, the iterative design process allows for a designer to interactively contribute to the design process of a machine assembly. These technical advantages offer one or more technological improvements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments.

FIG. 2 illustrates an example GUI and illustrates how machine design application obtains one or more design constraints via the GUI, according to various embodiments.

FIG. 3 illustrates an example GUI after machine design application has invoked machine generative ML model to generate a portion of a machine assembly, according to various embodiments.

FIG. 4 illustrates an example GUI after machine design application has invoked machine generative ML model to generate one or more machine assemblies, according to various embodiments.

FIG. 5 illustrates an example GUI illustrating design viewer after the user has selected iteration component, according to various embodiments.

FIG. 6 illustrates an example GUI illustrating design viewer after the user has selected iteration component, according to various embodiments.

FIG. 7 illustrates an example GUI illustrating an example of a branch viewing element, according to various embodiments.

FIG. 8 is a flow diagram of method steps for iteratively designing a machine assembly using machine generative ML model within machine design application, according to various embodiments.

FIG. 9 depicts one architecture of a system within which embodiments of the present disclosure may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details.

### System Overview

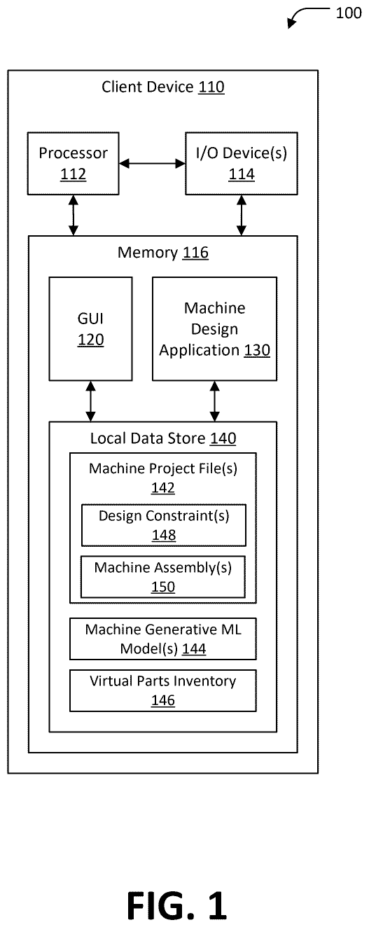

FIG. 1 is a conceptual illustration of a system 100 configured to implement one or more aspects of the various embodiments. As shown, in some embodiments, the system 100 includes, without limitation, a client device 110. The client device 110 includes, without limitation, a processor 112, one or more input/output (I/O) devices 114, and a memory 116. The memory 116 includes, without limitation, a graphical user interface (GUI) 120, a machine design application 130, and a local data store 140. The local data store 140 includes, without limitation, a machine project file 142, a machine generative ML model 144, and a virtual parts inventory 146. The machine project file 142 includes, without limitation, one or more design constraints 148 and a machine assembly 150.

Any number of the components of the system 100 can be distributed across multiple geographic locations or implemented in one or more cloud computing environments, that include encapsulated shared resources, software, and data, in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number or types of other devices, such as one or more other compute instances and/or a display device, into a client device. Some examples of client devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a machine design application 130 to generate a machine assembly 150 based on one or more design constraints 148 provided by a user. The machine design application 130 utilizes the machine generative ML model 144 to generate portions of a machine assembly 150 that represents the design. In one embodiment, the machine design application 130 receives user input from a designer via a GUI 120 and from data stored in or referenced by a machine project file 142. The user input can include one or more design constraints 148. Additionally, the machine design application 130 presents the portions of the machine assembly 150 for visualization within the GUI 120, allowing a designer to view or visually explore the portions of the machine assembly 150 generated by the machine generative ML model 144. As will be further described herein, the machine design application 130 also allows the designer to select a location or part within the visualized machine assembly 150 and request the machine design application 130 to generate an additional portion of the machine assembly 150. The selection of the location within the machine assembly 150 causes the machine design application 130 to invoke the machine generative ML model 144 to iteratively generate the additional portion of the machine assembly 150.

The additional portion of the machine assembly 150 can be connected to the selected location or part within the machine assembly 150. In some embodiments, the machine generative ML model 144 generates an additional portion by selecting one or more parts that form an iterative next step of the design before allowing the user to inspect and/or approve the additional portion. The user can also disapprove or roll back the additional portion of the design generated by the machine generative ML model 144. After rolling back the additional portion of the design, the user can select a different location or part of the machine assembly 150 and request the machine design application 130 to regenerate the additional portion. Alternatively, the user can roll back the additional portion of the design and request the machine design application 130 to generate an alternative additional portion of the machine assembly 150 from the same location or part. In some embodiments, the user can also select parts from the virtual parts inventory 146 and request the machine design application 130 to incorporate the selected parts into the additional portion of the machine assembly 150. In some embodiments, the machine design application 130 also allows the user to provide one or more parts in addition to one or more design constraints 148 as an input to the machine generative ML model 144 to generate an initial portion of the machine assembly 150.

One or more design constraints 148 can specify the various performance, material, or cost requirements specified by the designer on which the machine generative ML model 144 bases the generation of a portion of a machine assembly 150. A completed machine assembly 150 includes various parts that are linked together to create an output motion that includes an output force or output result based on the provided design constraints 148. For example, the one or more design constraints 148 can include an input motion type, such as a rotational motion, an oscillating motion, a reciprocating motion, a linear motion, or other types of motion. The one or more design constraints 148 can also specify an amount of force associated with the input motion.

One or more design constraints 148 can also include an output motion type, which can include one or more of the types of motion that are set forth above. The one or more design constraints 148 can further include a speed ratio that specifies a ratio of the output motion relative to the input motion. One or more design constraints 148 can also include an output position, specifying a location of the output motion relative to the input motion. For example, in the case of a transmission, the output position specifies a relative offset from the location of the input force being applied to an input of the machine assembly. In other words, the output position includes a plurality of coordinates specifying a height, a width, and a depth relative to the input force position. One or more design constraints 148 can also include an output motion direction, which specifies a direction, relative to a position of the output motion, that the output motion is provided by the machine assembly. Additionally, one or more design constraints 148 can further include an output motion sign that specifies whether the output motion is positive or negative relative to the input motion. Additionally, the one or more design constraints 148 can further specify a quantity of designs that should be generated by the machine generative ML model 144 in response to a request from the machine design application 130 or the designer.

In various embodiments, the processor 112 can be any instruction execution system, apparatus, or device capable of executing instructions. For example, the processor 112 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 112 is a programmable processor that executes program instructions to manipulate input data. In some embodiments, the processor 112 can include any number of processing cores, memories, and other modules for facilitating program execution.

I/O devices 114 include devices capable of providing input, such as a keyboard, a mouse, a touch-sensitive screen, and so forth, as well as devices capable of providing output, such as a display device. Additionally, I/O devices 114 may include devices capable of both receiving input and providing output, such as a touchscreen, a universal serial bus (USB) port, and so forth. I/O devices 114 may be configured to receive various types of input from an end-user, such as a designer of system 100, and to also provide various types of output to the end-user of system 100, such as displayed digital images, digital videos, or text. In some embodiments, one or more of I/O devices 114 are configured to couple the client device 110 to a network.

The memory 116 includes a memory module or a collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs, including the machine design application 130 and data for processing by the processor 112. In various embodiments, the memory 116 can include non-volatile memory, such as optical drives, magnetic drives, flash drives, or other storage. In some embodiments, separate data stores, such as one or more external data stores, can supplement the memory 116. In various embodiments, the machine design application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device, such as a smartphone, a server system, a cloud computing platform, etc., that communicates with the client device 110 via a network interface or an I/O devices interface.

The machine design application 130 resides in the memory 116 and executes on the processor 112 of the client device 110. The machine design application 130 interacts with an operator via the GUI 120. In some embodiments, the machine design application 130 and one or more separate applications (not shown) interact with the same operator via the GUI 120. In various embodiments, the machine design application 130 operates as a design studio or suite of tools that facilitate designing parts, machines, or other mechanical or electronic devices.

The GUI 120 can be any type of user interface that allows users to interact with one or more software applications via any number and/or types of GUI elements. The GUI 120 can be displayed in any technically feasible fashion on any number and/or types of stand-alone display devices, any number and/or types of display screens that are integrated into any number and/or types of user devices, or any combination thereof. The machine design application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry boxes, drop-down lists, and sliders. In some embodiments, the machine design application 130 organizes GUI elements into one or more container GUI elements, such as panels and/or panes.

The local data store 140 is part of the storage in the client device 110 that stores one or more machine project files 142 in a machine project. For example, a machine project can reference mechanical design elements, parts, images, videos, and other information that is stored in or referenced by a machine project file 142. A machine project file 142 can also store snapshots of the various stages of the design of a machine assembly 150. For example, a designer might generate a first stage of a machine assembly 150. From the first stage of the machine assembly 150, the machine design application 130 allows the user to generate separate design branches on which the designer iterates different designs of respective machine assemblies 150. In this way, the designer can generate divergent designs using the machine design application 130 and the machine generative ML model 144 while retaining each iterative step in the design process. Additionally, the machine design application 130 can also allow a designer to create sub-branches from a design branch so that any number of design concepts can be generated and explored using the machine design application 130 and the machine generative ML model 144.

The machine generative ML model 144 represents one or more ML models that have been trained on a relatively large amount of existing data and optionally any number of results to perform any number and/or types of generative tasks based on patterns detected in the existing data. The machine generative ML model 144 represents a generative model that receives one or more design constraints 148 as inputs and generates one or more machine assemblies as outputs. The machine generative ML model 144 can be executed by the client device 110 or remotely executed and accessible to the machine design application 130 via an application programming interface with which the machine design application 130 submits the one or more design constraints 148 and receives one or more machine assemblies from the machine generative ML model 144 in response.

The machine generative ML model 144 is a machine learning model that has been trained on a corpus of training data. The machine generative ML model 144 can have any suitable architecture and be trained in any technically feasible manner in some embodiments. For example, in some embodiments, the machine generative ML model 144 can include an artificial neural network, such as a large language model, a small language model, or the like. In some embodiments, the machine generative ML model 144 can be fine-tuned on domain-specific training data after an initial training or, alternatively, may have received no additional training beyond the initial training to generate a machine assembly 150 in a file format that can be utilized by the machine design application 130. In some embodiments, the machine generative ML model 144 can include a single language model, a plurality of different language models, or multiple instances of a single language model.

The virtual parts inventory 146 specifies one or more parts that can be utilized by the machine design application 130 to generate portions of a machine assembly 150. In some embodiments, the virtual parts inventory 146 can be used alongside one or more design constraints 148 that are provided to the machine generative ML model 144 so that the machine generative ML model 144 uses only parts that exist in the virtual parts inventory to create machine assemblies. The virtual parts inventory could be associated with an inventory of parts available to a manufacturer, for example. Parts within the virtual parts inventory 146 can be associated with various part metadata, such as a part type, part material, weight, cost, or other information that can be extracted by the machine design application 130 and displayed in the GUI 120. Additionally, the part metadata can be used as a design constraint for a particular machine assembly 150 that is being generated by the machine design application 130.

As described above, the machine design application 130 receives one or more design constraints 148 from a GUI 120 as an input. In some implementations, the one or more design constraints 148 can include a text or audio prompt from which the machine design application 130 generates one or more design constraints 148. In another example, the one or more design constraints 148 are obtained from the GUI 120 of the machine design application 130. For example, the GUI 120 can allow a designer to specify various properties of an input force, input motion, output ratio, output motion, and other design constraints 148.

The machine design application 130 provides the one or more design constraints 148 to the machine generative ML model 144. The machine generative ML model 144 generates a portion of a machine assembly 150, such as the first part or a first series of parts, based on the one or more design constraints 148. The portion of the machine assembly 150 is associated with or saved within a machine project file 142. The portion of the machine assembly 150 can identify the part or series of parts as well as how the parts link together. The portion of the machine assembly 150 is also generated by the local data store 140 to satisfy the one or more design constraints 148. The machine design application 130 can display the portion of the machine assembly 150 in the GUI 120 and allow the user to select a location or a part within the portion of the machine assembly 150. In some embodiments, the machine design application 130 can also display a preview of multiple possible portions of the machine assembly 150 generated by the machine design application 130 and allow the designer to select one of the portions in the GUI 120.

In response to the user selecting a location or part within the displayed machine assembly 150, the machine design application 130 invokes the machine generative ML model 144 and provides the portion of the machine assembly 150 along with the one or more design constraints 148. The machine design application 130 also provides the selected portion of the machine assembly 150 to the machine generative ML model 144. In one example, the machine design application 130 provides the portion of the machine assembly 150 by translating the machine assembly 150 into a series of textual tokens expressed in a domain-specific language (DSL) that facilitates translation of the machine assembly 150 to and from a textual representation. The machine generative ML model 144 receives the textual representation of the portion of the machine assembly 150, a textual identification of the location or part within the machine assembly 150 selected by the designer, the one or more design constraints 148, and any other user selections or preferences.

The machine generative ML model 144 generates a new portion of the machine assembly 150 by identifying a next part compatible with or connectable to the portion of the machine assembly 150. In one embodiment, the machine design application 130 requests the machine generative ML model 144 to generate a completed machine assembly 150 based on the user selection and displays only the next part or series of parts that are compatible with or connectable to the portion of the machine assembly 150. In another embodiment, the machine design application 130 requests the machine generative ML model 144 to generate only the next part or series of parts that are compatible with or connectable to the portion of the machine assembly 150.

The user or designer can progress through a series of iterative interactions with the machine design application 130 via the GUI 120 to select a part or a portion of the machine assembly 150 from which the machine design application 130 causes the machine generative ML model 144 to generate or identify a next part or series of parts. Each iteration of the machine assembly 150 can be saved in association with a machine project file 142. The machine design application 130 also provides, via the GUI 120, mechanisms by which the user can view each iterative step of the design process and create branches and/or sub-branches of a design of a machine assembly 150, as will be shown in the figures discussed herein.

### Example User Interface

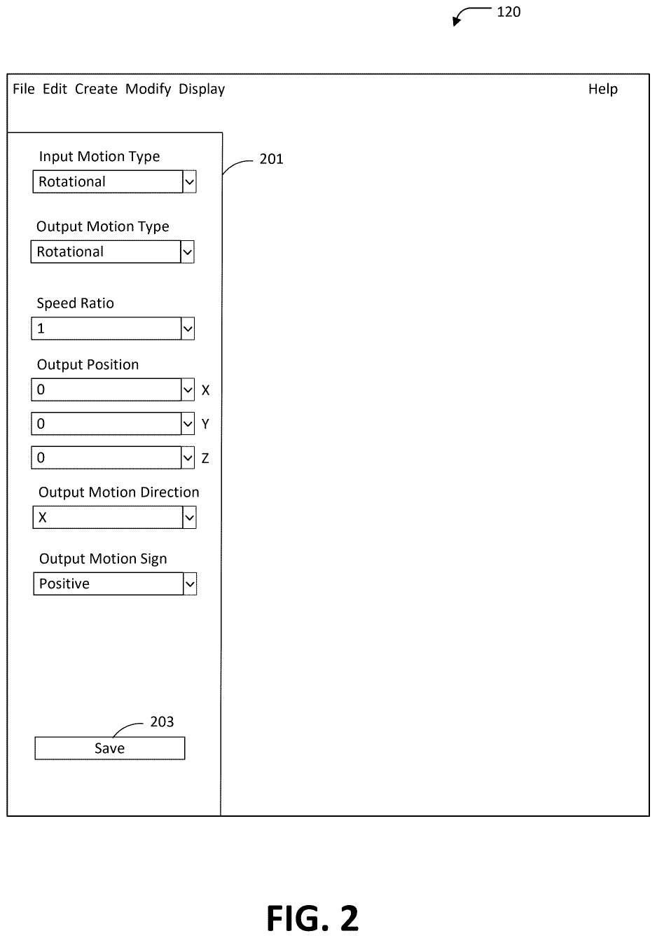

FIG. 2 illustrates an example GUI 120 and illustrates how machine design application 130 obtains one or more design constraints 148 via the GUI 120 according to various embodiments. In the example GUI 120 of FIG. 2, a requirements panel 201 is shown in which the user defines the one or more design constraints 148 from which machine assembly 150 is generated by machine generative ML model 144.

Within the GUI 120, requirements panel 201 serves as one of the primary interfaces in which a designer specifies the various requirements and constraints for a machine assembly. The requirements panel 201 allows a designer to specify material preferences, size restrictions, environmental conditions, performance criteria, and other parameters that comprise one or more design constraints 148 that can be provided to machine generative ML model 144 according to various embodiments.

Requirements panel 201 includes one or more fields for textual inputs, dropdowns for predefined values, sliders for ranges, or other user interface components that allow the designer to specify the one or more design constraints 148 that will be used to generate the machine assembly 150. In some cases, machine design application 130 performs validation of the inputs to the requirements panel 201 to ensure that necessary requirements are met and logically compatible, offering suggestions if conflicts arise between parameters. Such validation allows machine design application 130 to maintain coherence across the inputs provided in requirements panel 201 and helps the user in providing meaningful data via requirements panel 201 as one or more design constraints 148 that will be provided to machine generative ML model 144.

In the GUI 120 shown in FIG. 2, once the user has specified the one or more design constraints 148 using the requirements panel 201, the user can activate the generation user interface element 203, which invokes the machine generative ML model 144 to generate a first portion of a machine assembly 150 based on the one or more design constraints 148 defined in the requirements panel 201. In some embodiments, the user can also select a part from virtual parts inventory 146 using the GUI 120. The selected part is used by machine design application 130 to base the creation of the portion of the machine assembly 150. For example, machine design application 130 converts the one or more design constraints 148 to textual tokens and provides the textual tokens to machine generative ML model 144. Machine design application 130 can also translate a user selected part to one or more textual tokens and provide the textual tokens to the machine generative ML model 144 along with the one or more design constraints 148.

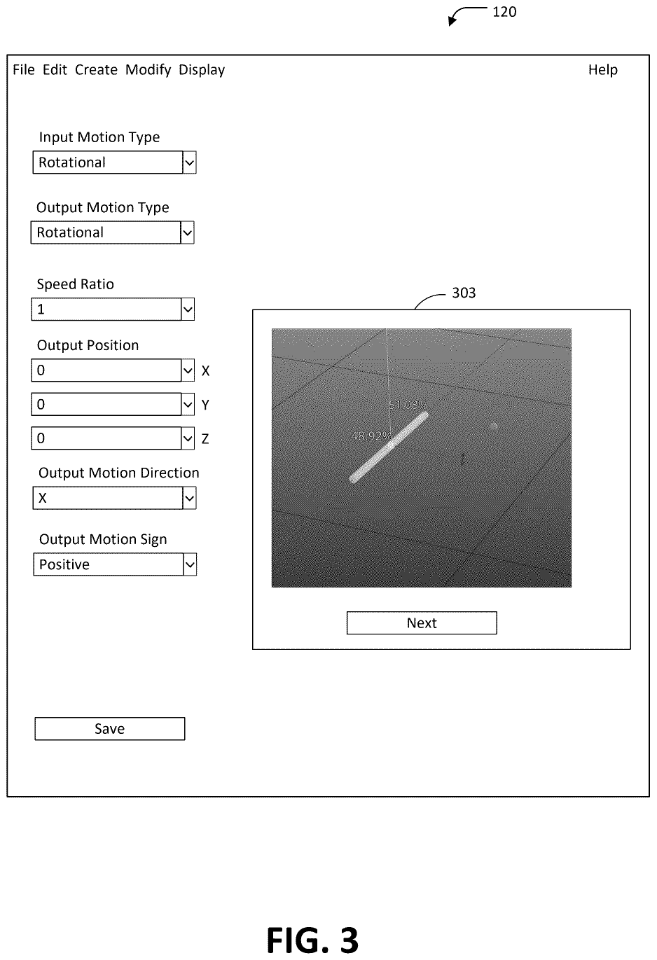

FIG. 3 illustrates an example GUI 120 after machine design application 130 has invoked machine generative ML model 144 to generate a portion of a machine assembly 150 according to various embodiments. The portion of the machine assembly 150 is saved in association with machine project file 142 as a snapshot of the design of machine assembly 150 in a branch of the design of the machine assembly 150 that is represented in the machine project file 142. In the example GUI 120 of FIG. 3, a design viewer 303 is shown. In design viewer 303, the machine design application 130 displays the portion of the design generated by machine generative ML model 144 based on the one or more design constraints 148 and/or one or more parts from virtual parts inventory 146 that are selected by a user on which to base a machine assembly 150. The illustrated portion of the machine assembly 150 represents a part from virtual parts inventory 146 that the user can view, rotate, or otherwise manipulate to explore the design of the portion of the machine assembly 150. In some embodiments, the GUI 120 can also display other information about the portion of the machine assembly 150, such as part metadata, a weight of the parts associated with the portion of the machine assembly 150, cost information, or other data.

In one example, the machine design application 130 calculates an overall constraint satisfaction score for the portion of the machine assembly 150. The overall constraint satisfaction score can represent a degree to which the portion of the machine assembly 150 complies with one or more design constraints 148. Machine design application 130 can display the overall constraint satisfaction score in the GUI 120.

In some examples, machine design application 130 presents multiple portions of one or more machine assemblies 150 that are displayed as individual cards in a grid format, carousel format, scrollable format, or other formats. Each card within GUI 120 can include a different portion of an assembly design 150 as well as a thumbnail image. Each card further includes a summary of details, such as constraint satisfaction, material, weight, estimated cost, assembly time, and other high-impact metrics. Designers can click on any card to open a more detailed view of the portion of the machine assembly 150. The cards can also incorporate a rating or tagging system to help the designer quickly note which portions of designs are preferred, facilitating comparison and filtering of alternatives.

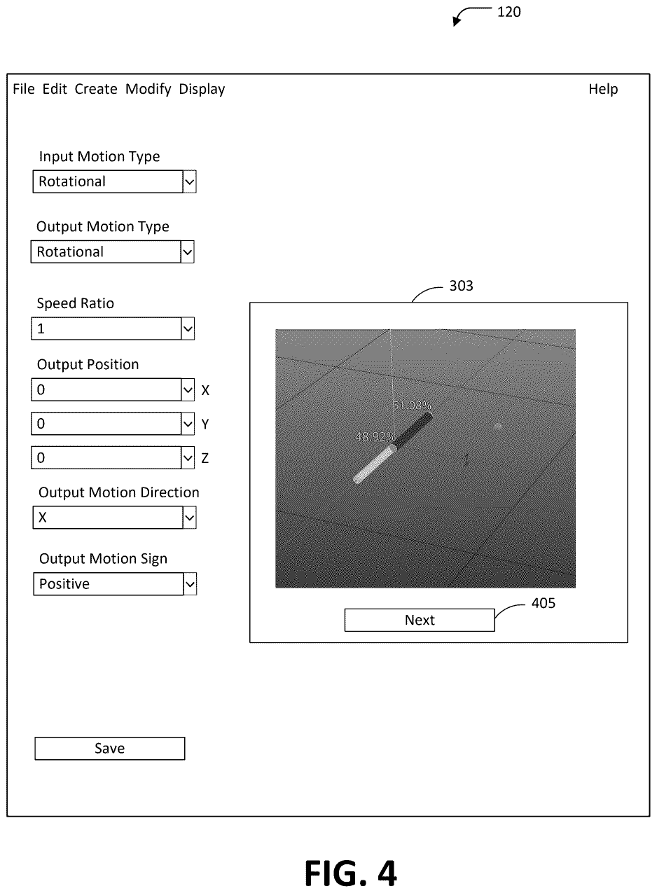

FIG. 4 illustrates an example GUI 120 illustrating how a user can iteratively utilize machine design application 130 and machine generative ML model 144 to generate a subsequent portion of machine assembly 150 according to various embodiments. In the example of FIG. 4, the user has selected or hovered a pointer over a location or a portion of a part within the design viewer 303. Machine design application 130 can highlight or otherwise indicate that the user has selected or hovered the pointer over the location or portion of the part.

Different parts in the portion of the machine assembly 150 can have different selectable locations or parts. For example, in the case of a shaft, the selection can occur at either end of the shaft. In the case of a gear, a selection can occur at one or more locations along the circumference of the gear. For an elongated gear, selection can occur along any portion of the elongated shaft forming the gear or at one or more locations along the circumference of the gear. In the case of a belt, selection can occur along any portion of the belt. Similarly, selection on a pulley can occur at the rotational component of the pulley or along any portion of the pulley. In the case of a chain or sprocket, selection can occur on one or more of the interconnected links for engagement with another component. The designer can also select other locations or parts within a displayed portion of machine assembly 150. For example, a screw, nut, bolt, rivet, bearing, coupling, or other portion of machine assembly 150 can be selected by the user.

Upon selecting a location or part within the machine assembly 150 displayed in design viewer 303, the user can select an iteration component 405 within the GUI 120 of machine design application 130. The iteration component 405 causes machine design application 130 to invoke the machine generative ML model 144 to generate a next portion of the machine assembly 150. The next portion of the machine assembly 150 can be saved in a branch of the design of the machine assembly 150 that is represented in machine project file 142. The previous portion of the machine assembly 150 is also saved in association with the same machine project file 142.

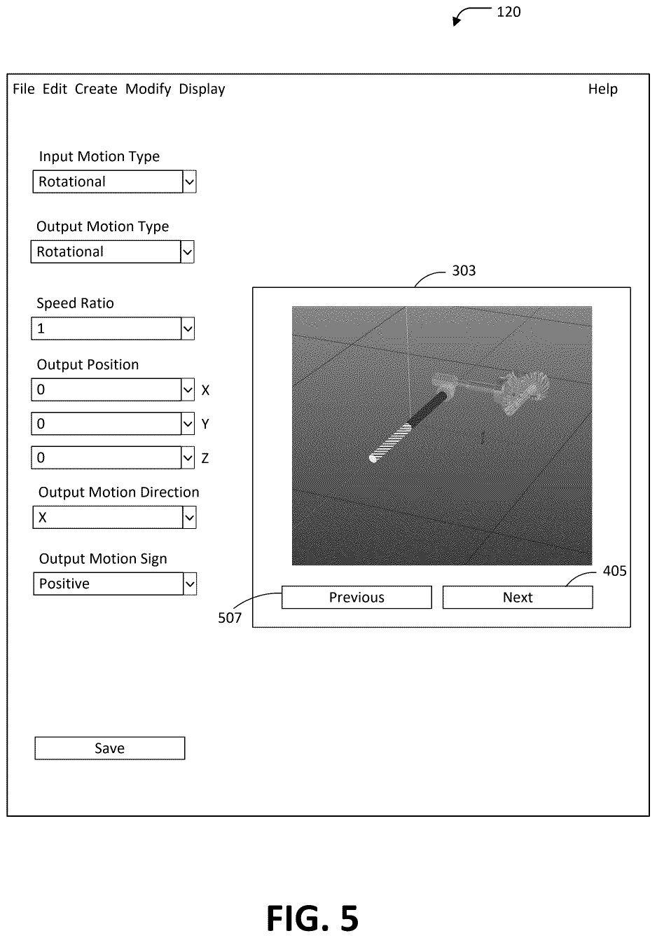

FIG. 5 illustrates an example GUI 120 illustrating design viewer 303 after the user has selected iteration component 405 according to various embodiments. In the example of FIG. 5, machine design application 130 has invoked machine generative ML model 144 to generate a next portion of the machine assembly 150 that is displayed in design viewer 303. As noted above, machine design application 130 provides one or more textual tokens representing the portion of the machine assembly 150 along with one or more textual tokens representing the location or part within the portion of machine assembly 150 selected by the designer. Textual tokens representing the one or more design constraints 148 are also provided to machine generative ML model 144. Machine generative ML model 144, in response, generates an additional portion of machine assembly 150 and returns one or more textual tokens representing the additional portion of machine assembly 150 to machine design application 130. In some embodiments, machine generative ML model 144 returns a completed machine assembly 150 to machine design application 130, and machine design application 130 selects one or more parts that are connected to the user-selected location or part within the previous portion of the machine assembly 150.

In response to receiving the selected location or part within the machine assembly 150 and the one or more design constraints 148, machine generative ML model 144 generates the next portion of the machine assembly 150 and returns the next portion to machine design application 130. Machine design application 130 displays the next portion of the machine assembly 150 in design viewer 303. The next portion of the machine assembly 150 can be displayed in design viewer 303 as a 3D model that the user can manipulate and explore. Machine design application 130 also provides a previous portion component 507 in the GUI 120. The previous portion component 507 allows the user to roll back the generated portion of the machine assembly 150 displayed in design viewer 303 to the previous portion shown in the example of FIG. 4.

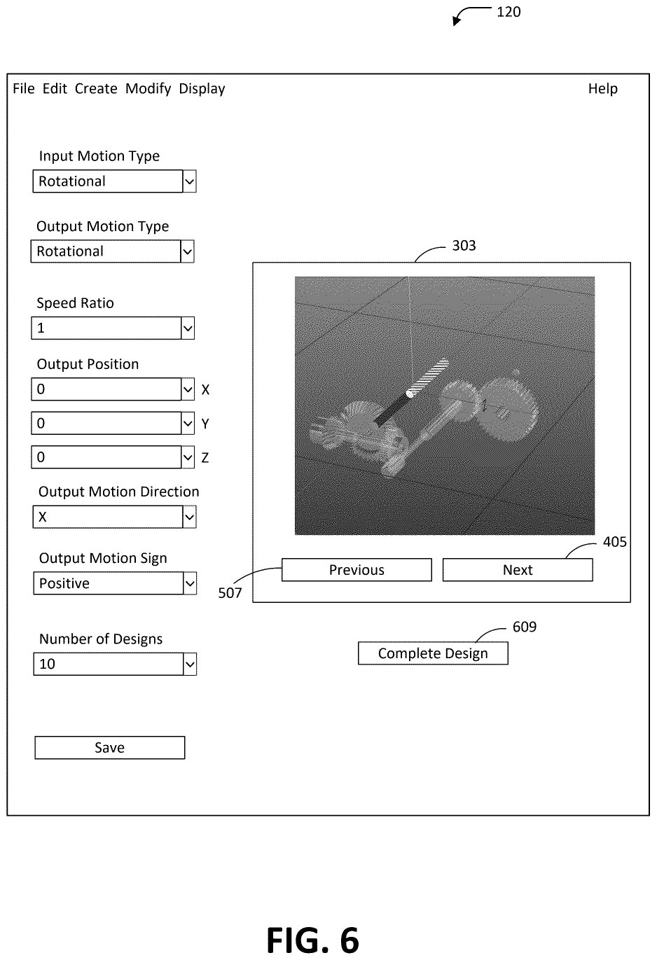

FIG. 6 illustrates an example GUI 120 illustrating design viewer 303 after the user has selected iteration component 405 according to various embodiments. The example of FIG. 6 continues the example of FIG. 3 if the user had selected a different location or part within the portion of the machine assembly 150 shown in design viewer 303. Alternatively, the example of FIG. 6 also illustrates a scenario in which the user rolls back the portions of the machine assembly 150 shown in FIGS. 4 and 5 to select a different location or part within the portion of the machine assembly 150 shown in design viewer 303. In the example of FIG. 6, machine design application 130 has again invoked machine generative ML model 144 to generate a next portion of the machine assembly 150 that is displayed in design viewer 303. As noted above, machine design application 130 provides one or more textual tokens representing the portion of the machine assembly 150 along with one or more textual tokens representing the location or part within the portion of machine assembly 150 selected by the designer. Textual tokens representing the one or more design constraints 148 are also provided to machine generative ML model 144. Machine generative ML model 144, in response, generates an additional portion of machine assembly 150 and returns one or more textual tokens representing the additional portion of machine assembly 150 to machine design application 130. In some embodiments, machine generative ML model 144 returns a completed machine assembly 150 to machine design application 130, and machine design application 130 selects one or more parts that are connected to the user-selected location or part within the previous portion of the machine assembly 150.

As shown in FIG. 6, the portion of the machine assembly 150 generated by machine generative ML model 144 and displayed within design viewer 303 by machine design application 130 is different from the example of FIG. 5. This scenario indicates how the designer can iteratively utilize the machine generative ML model 144 to generate a machine assembly 150 by selecting or editing the design as the machine generative ML model 144 generates the design step-by-step. In some embodiments, the user can also request, via the GUI 120, that machine design application 130 generate a completed design of the machine assembly 150 based on the portion of the machine assembly 150 shown in design viewer 303. In one example, the user can select the complete design element 609 to generate a remainder of the machine assembly 150 according to the one or more design constraints 148. The machine design application 130 provides the existing portion of the machine assembly 150 to machine generative ML model 144 along with the one or more design constraints 148. Machine generative ML model 144 returns one or more textual tokens representing the completed design of machine assembly 150 to machine design application 130, which displays the completed design in GUI 120.

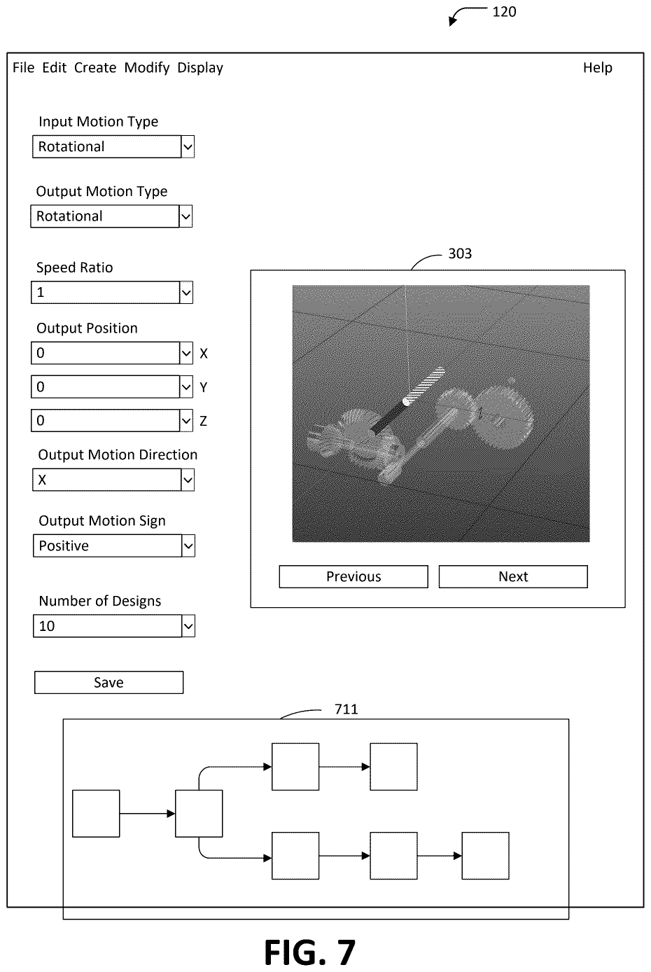

FIG. 7 illustrates an example GUI 120 illustrating an example of a branch viewing element 711. Machine design application 130 generates branch viewing element 711 within GUI 120 to provide the designer with a mechanism to explore various design branches generated using the iterative design process facilitated by machine design application 130. For example, the user can generate a first portion of a machine assembly 150 as in the scenario of FIG. 5. The user can generate an alternative portion of a machine assembly 150 as in the scenario of FIG. 6. Both versions of the machine assembly 150 can be saved in association with machine project file 142 and provided in the GUI 120 so that the user can retain and iterate the design of the machine assembly 150 based on the different design branches.

To further illustrate, a user can select a first location or part within an initial portion of a machine assembly 150 and request the machine design application 130 to generate a next portion of the machine assembly 150. The machine generative ML model 144 generates the portion of the machine assembly 150 shown in the example of FIG. 5 by identifying one or more parts that are compatible with or connectable to the first location or part, taking into account the one or more design constraints 148. The user can return to the initial portion of the machine assembly 150 and select a second location or part within the initial portion of the machine assembly 150. The machine generative ML model 144 then generates a different portion of the machine assembly 150 based on one or more parts that are compatible with or connectable to the second location or part, taking into account the one or more design constraints 148. Both portions of the machine assembly 150 are saved in different design branches and are also saved in association with machine project file 142.

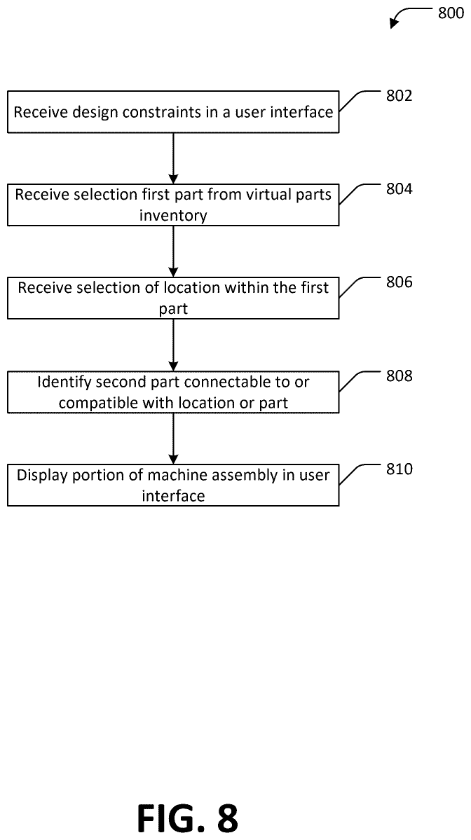

FIG. 8 is a flow diagram of method steps for iteratively designing a machine assembly 150 using machine generative ML model 144 within machine design application 130, according to various embodiments. Although the method steps are described in conjunction with the systems of FIGS. 1-7, persons skilled in the art will understand that any system configured to perform the method steps in any order falls within the scope of the present disclosure.

As shown, a method 800 begins at operation 802, where machine design application 130 receives one or more design constraints 148. The one or more design constraints 148 are obtained via a GUI 120 and can be specified by a user. The one or more design constraints 148 specify one or more aspects of a desired machine generated by machine generative ML model 144.

At operation 804, machine design application 130 receives a selection of a part in a user interface, wherein the part is selected from virtual parts inventory 146. The part can comprise a portion of machine assembly 150. In some embodiments, the part can include a preexisting machine assembly 150 or a series of parts from the virtual parts inventory 146. In some embodiments, the part can be identified by machine generative ML model 144 based on the one or more design constraints 148 received at operation 802. The portion of machine assembly 150 can be displayed in a GUI 120 generated by machine design application 130 in various embodiments.

At operation 806, machine design application 130 receives selection of a location or a part within the portion of the machine assembly 150. The selection can include a user selection via a GUI 120 generated by machine design application 130. The selection can involve a location of a shaft, gear, or another portion of the machine assembly 150 identified at operation 804.

At operation 808, machine design application 130 identifies a second part or series of parts that are connectable to or compatible with the portion of the machine assembly 150 identified at operation 804. In one embodiment, machine design application 130 requests the machine generative ML model 144 to convert one or more design constraints 148 to textual tokens and provide the textual tokens to machine generative ML model 144. For example, machine design application 130 converts one or more design constraints 148 to textual tokens and provides the textual tokens to machine generative ML model 144. Machine design application 130 also translates the portion of the machine assembly 150 to textual tokens. Machine design application 130 can also translate a selected part or location within the machine assembly 150 to one or more textual tokens. The textual tokens are provided to the machine generative ML model 144 along with a prompt to generate a next portion of the design of the machine assembly 150.

At operation 810, machine design application 130 displays the portion of machine assembly 150 generated by machine generative ML model 144 in GUI 120.

The portion of the machine assembly 150 is generated by machine generative ML model 144 in response to the machine design application 130 providing textual tokens that describe a previous portion of the machine assembly 150, a selected location or part within the previous portion of the machine assembly 150, and one or more design constraints 148. In some cases, machine design application 130 can also provide a prompt to generate a next portion of the design of the machine assembly 150.

### System Implementation

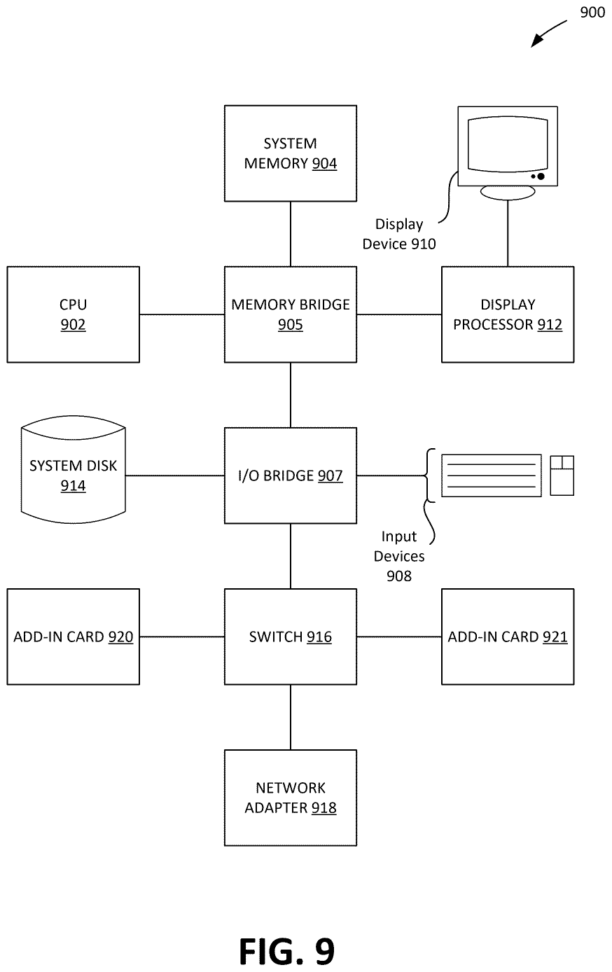

FIG. 9 is a more detailed illustration of a computing device that can implement the functionalities of the entities illustrated in FIG. 1, according to various embodiments. This figure in no way limits or is intended to limit the scope of the various embodiments. In various implementations, system 900 may be an augmented reality, virtual reality, or mixed reality system or device, a personal computer, video game console, personal digital assistant, mobile phone, mobile device or any other device suitable for practicing the various embodiments. Further, in various embodiments, any combination of two or more systems 900 may be coupled together to practice one or more aspects of the various embodiments.

As shown, system 900 includes a central processing unit (CPU) 902 and a system memory 904 communicating via a bus path that may include a memory bridge 905. CPU 902 includes one or more processing cores, and, in operation, CPU 902 is the master processor of system 900, controlling and coordinating operations of other system components. System memory 904 stores software applications and data for use by CPU 902. CPU 902 runs software applications and optionally an operating system. Memory bridge 905, which may be, e.g., a Northbridge chip, is connected via a bus or other communication path (e.g., a HyperTransport link) to an I/O (input/output) bridge 907. I/O bridge 907, which may be, e.g., a Southbridge chip, receives user input from one or more user input devices 908 (e.g., keyboard, mouse, joystick, digitizer tablets, touch pads, touch screens, still or video cameras, motion sensors, and/or microphones) and forwards the input to CPU 902 via memory bridge 905.

A display processor 912 is coupled to memory bridge 905 via a bus or other communication path (e.g., a PCI Express, Accelerated Graphics Port, or HyperTransport link); in one embodiment display processor 912 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 904.

Display processor 912 periodically delivers pixels to a display device 910 (e.g., a screen or conventional CRT, plasma, OLED, SED or LCD based monitor or television). Additionally, display processor 912 may output pixels to film recorders adapted to reproduce computer generated images on photographic film. Display processor 912 can provide display device 910 with an analog or digital signal. In various embodiments, one or more of the various graphical user interfaces set forth in FIG. 3 are displayed to one or more users via display device 910, and the one or more users can input data into and receive visual output from those various graphical user interfaces.

A system disk 914 is also connected to I/O bridge 907 and may be configured to store content and applications and data for use by CPU 902 and display processor 912. System disk 914 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 916 provides connections between I/O bridge 907 and other components such as a network adapter 918 and various add-in cards. Network adapter 918 allows system 900 to communicate with other systems via an electronic communications network and may include wired or wireless communication over local area networks and wide area networks such as the Internet.

Other components (not shown), including USB or other port connections, film recording devices, and the like, may also be connected to I/O bridge 907. For example, an audio processor may be used to generate analog or digital audio output from instructions and/or data provided by CPU 902, system memory 904, or system disk 914. Communication paths interconnecting the various components in FIG. 9 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 912 incorporates circuitry optimized for graphics and video processing, including, for example, video output circuitry, and constitutes a graphics processing unit (GPU). In another embodiment, display processor 912 incorporates circuitry optimized for general purpose processing. In yet another embodiment, display processor 912 may be integrated with one or more other system elements, such as the memory bridge 905, CPU 902, and I/O bridge 907 to form a system on chip (SoC). In still further embodiments, display processor 912 is omitted and software executed by CPU 902 performs the functions of display processor 912.

Pixel data can be provided to display processor 912 directly from CPU 902. In some embodiments, instructions and/or data representing a scene are provided to a render farm or a set of server computers, each similar to system 900, via network adapter 918 or system disk 914. The render farm generates one or more rendered images of the scene using the provided instructions and/or data. These rendered images may be stored on computer-readable media in a digital format and optionally returned to system 900 for display. Similarly, stereo image pairs processed by display processor 912 may be output to other systems for display, stored in system disk 914, or stored on computer-readable media in a digital format.

Alternatively, CPU 902 provides display processor 912 with data and/or instructions defining the desired output images, from which display processor 912 generates the pixel data of one or more output images, including characterizing and/or adjusting the offset between stereo image pairs. The data and/or instructions defining the desired output images can be stored in system memory 904 or graphics memory within display processor 912. In an embodiment, display processor 912 includes 3D rendering capabilities for generating pixel data for output images from instructions and data defining the geometry, lighting shading, texturing, motion, and/or camera parameters for a scene. Display processor 912 can further include one or more programmable execution units capable of executing shader programs, tone mapping programs, and the like.

Further, in other embodiments, CPU 902 or display processor 912 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 902, display processor 912, or one or more other processing devices or any combination of these different processors.

CPU 902, render farm, and/or display processor 912 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 900 may be a robot or robotic device and may include CPU 902 and/or other processing units or devices and system memory 904. In such embodiments, system 900 may or may not include other elements shown in FIG. 9. System memory 904 and/or other memory units or devices in system 900 may include instructions that, when executed, cause the robot or robotic device represented by system 900 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 904 is connected to CPU 902 directly rather than through a bridge, and other devices communicate with system memory 904 via memory bridge 905 and CPU 902. In other alternative topologies display processor 912 is connected to I/O bridge 907 or directly to CPU 902, rather than to memory bridge 905. In still other embodiments, I/O bridge 907 and memory bridge 905 might be integrated into a single chip. The particular components shown herein are optional; for instance, any number of add-in cards or peripheral devices might be supported. In some embodiments, switch 916 is eliminated, and network adapter 918 and add-in cards 620, 621 connect directly to I/O bridge 907.

In sum, the disclosed techniques provide methods for the iterative design of machine assemblies using a machine learning model. The machine assemblies include one or more parts that adhere to one or more design constraints. A designer can select a location or part within a portion of a machine assembly and request a generative ML model to generate a subsequent portion of the machine assembly. Consequently, instead of relying solely on the generative ML model to generate a completed design, the designer can engage in an iterative design process through a user interface. The disclosed techniques allow for a designer to influence the creation of a machine assembly by a ML model by participating in the iterative design process rather than relying on the ML model to generate a completed machine assembly without user input.

At least one technical advantage of the disclosed techniques relative to the prior art is that the disclosed techniques provide mechanisms to iteratively generate machine assemblies using a generative machine learning (ML) model. In particular, the disclosed techniques provide a mechanism for a designer to interactively and iteratively participate in the design of machine assemblies while relying on an ML model to generate one or more aspects of the design. Iterative generation of machine assemblies allows for generated machine assemblies that more closely align with designer preferences and improved quality as opposed to relying on an ML model to generate completed designs that might not align with designer preferences. Furthermore, the disclosed techniques enable a designer to provide design constraints to the ML model and deliver granular feedback on the direction in which the ML model iterates the design of the machine assembly. Again, the iterative design process allows for a designer to interactively contribute to the design process of a machine assembly. By These technical advantages offer one or more technological improvements over prior art approaches.

1. In some embodiments, a computer-implemented method for iteratively generating machine assemblies according to design constraints comprises receiving a plurality of design constraints that define properties of a machine assembly, receiving a first selection of a first part via a user interface, the first part selected from a virtual parts inventory, identifying, via a generative machine learning model, a second part from the virtual parts inventory, the second part connectable to the first part based on the plurality of design constraints and a second selection of a first location within the first part, and displaying the first part and the second part in the user interface, wherein the first part and the second part comprise a first portion of the machine assembly.

2. The computer-implemented method of clause 1, further comprising receiving a third selection of the second part in the user interface, wherein the second part is selected from the virtual parts inventory.

3. The computer-implemented method of clauses 1 or 2, wherein the second selection of the first location within the first part comprises a selection in the user interface of a selectable portion of the first part.

4. The computer-implemented method of any of clauses 1-3, wherein the first location of the first part comprises an end of a shaft from the virtual parts inventory.

5. The computer-implemented method of any of clauses 1-4, wherein the first location of the first part comprises a portion of a gear from the virtual parts inventory.

6. The computer-implemented method of any of clauses 1-5, further comprising generating, using the generative machine learning model, a remainder of the machine assembly based on the first part and the second part, and displaying the remainder of the machine assembly in the user interface.

7. The computer-implemented method of any of clauses 1-6, further comprising receiving a fourth selection of a second portion of the first part in the user interface, identifying, using the generative machine learning model, a third part from the virtual parts inventory connectable to the first part based on the fourth selection of the second portion of the first part, and displaying the first part and the third part in the user interface without the second part, wherein the first part and the third part comprise a second portion of the machine assembly.

8. The computer-implemented method of any of clauses 1-7, further comprising saving, in a data store, the first portion of the machine assembly as a first design branch.

9. The computer-implemented method of any of clauses 1-8, further comprising generating a second design branch associated with the machine assembly, wherein the second design branch is associated with a second portion of the machine assembly that is different from the first portion of the machine assembly.

10. The computer-implemented method of any of clauses 1-9, further comprising generating a plurality of textual tokens associated with plurality of design constraints and the first selection of the first part, the method further comprising providing the plurality of textual tokens to the generative machine learning model.

11. The computer-implemented method of any of clauses 1-10, wherein the first selection of the first part is identified by the generative machine learning model based on the plurality of design constraints.

12. In some embodiments, one or more non-transitory computer-readable storage media include instructions that, when executed by at least one processor, cause the at least one processor to perform steps for iteratively generating machine assemblies according to design constraints, the steps comprising receiving a plurality of design constraints that define properties of a machine assembly, receiving a first selection of a first part via a user interface, the first part selected from a virtual parts inventory, identifying, using a generative machine learning model, a second part from the virtual parts inventory, the second part connectable to the first part based on the plurality of design constraints and a second selection of a first location within the first part, and displaying the first part and the second part in a user interface, wherein the first part and the second part comprise a first portion of the machine assembly.

13. The one or more non-transitory computer-readable storage media of clause 12, wherein the instructions, when executed by the at least one processor, further cause the at least one processor to perform steps comprising further comprising receiving a third selection of the second part in the user interface, wherein the second part is selected from the virtual parts inventory.

14. The one or more non-transitory computer-readable storage media of clauses 12 or 13, wherein the second selection of the first location within the first part comprises a selection in the user interface of a selectable portion of the first part.

15. The one or more non-transitory computer-readable storage media of any of clauses 12-14, wherein the instructions, when executed by the at least one processor, further cause the at least one processor to perform steps comprising generating, using the generative machine learning model, a remainder of the machine assembly based on the first part and the second part, and displaying the remainder of the machine assembly in the user interface.

16. The one or more non-transitory computer-readable storage media of any of clauses 12-15, wherein the instructions, when executed by the at least one processor, further cause the at least one processor to perform steps comprising receiving a fourth selection of a second portion of the first part in the user interface, identifying, using the generative machine learning model, a third part from the virtual parts inventory connectable to the first part based on the fourth selection of the second portion of the first part, and displaying the first part and the third part in the user interface without the second part, wherein the first part and the third part comprise a second portion of the machine assembly.

17. The one or more non-transitory computer-readable storage media of any of clauses 12-16, wherein the instructions, when executed by the at least one processor, further cause the at least one processor to perform steps comprising saving, in a data store, the first portion of the machine assembly as a first design branch.

18. The one or more non-transitory computer-readable storage media of any of clauses 12-17, wherein the instructions, when executed by the at least one processor, further cause the at least one processor to perform steps comprising generating a second design branch associated with the machine assembly, wherein the second design branch is associated with a second portion of the machine assembly that is different from the first portion of the machine assembly.

19. The one or more non-transitory computer-readable storage media of any of clauses 12-18, wherein the instructions, when executed by the at least one processor, further cause the at least one processor to perform steps comprising generating at a plurality of textual tokens associated with plurality of design constraints and the first selection of the first part, the instructions further causing the at least one processor to at least provide the plurality of textual tokens to the generative machine learning model.

20. In some embodiments, a system comprises one or more memories storing instructions, and one or more processors that are coupled to the one or more memories and, when executing the instructions, are configured to perform steps for iteratively generating machine assemblies according to design constraints, the steps comprising receiving a plurality of design constraints that define properties of a machine assembly, receiving a first selection of a first part via a user interface, the first part selected from a virtual parts inventory, identifying, using a generative machine learning model, a second part from the virtual parts inventory, the second part connectable to the first part based on the plurality of design constraints and a second selection of a first location within the first part, and displaying the first part and the second part in a user interface, wherein the first part and the second part comprise a first portion of the machine assembly.

Any and all combinations of any of the claim elements recited in any of the claims and/or any elements described in this application, in any fashion, fall within the contemplated scope of the present invention and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer. ” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for iteratively generating machine assemblies according to design constraints, the method comprising:
receiving a plurality of design constraints that define properties of a machine assembly;
receiving a first selection of a first part via a user interface, the first part selected from a virtual parts inventory;
identifying, via a generative machine learning model, a second part from the virtual parts inventory, the second part connectable to the first part based on the plurality of design constraints and a second selection of a first location within the first part; and
displaying the first part and the second part in the user interface, wherein the first part and the second part comprise a first portion of the machine assembly.

2. The computer-implemented method of claim 1, further comprising receiving a third selection of the second part in the user interface, wherein the second part is selected from the virtual parts inventory.

3. The computer-implemented method of claim 1, wherein the second selection of the first location within the first part comprises a selection in the user interface of a selectable portion of the first part.

4. The computer-implemented method of claim 3, wherein the first location of the first part comprises an end of a shaft from the virtual parts inventory.

5. The computer-implemented method of claim 3, wherein the first location of the first part comprises a portion of a gear from the virtual parts inventory.

6. The computer-implemented method of claim 1, further comprising:
generating, using the generative machine learning model, a remainder of the machine assembly based on the first part and the second part; and
displaying the remainder of the machine assembly in the user interface.

7. The computer-implemented method of claim 1, further comprising:
receiving a fourth selection of a second portion of the first part in the user interface;
identifying, using the generative machine learning model, a third part from the virtual parts inventory connectable to the first part based on the fourth selection of the second portion of the first part; and
displaying the first part and the third part in the user interface without the second part, wherein the first part and the third part comprise a second portion of the machine assembly.

8. The computer-implemented method of claim 1, further comprising saving, in a data store, the first portion of the machine assembly as a first design branch.

9. The computer-implemented method of claim 8, further comprising generating a second design branch associated with the machine assembly, wherein the second design branch is associated with a second portion of the machine assembly that is different from the first portion of the machine assembly.

10. The computer-implemented method of claim 1, further comprising generating a plurality of textual tokens associated with plurality of design constraints and the first selection of the first part, the method further comprising providing the plurality of textual tokens to the generative machine learning model.

11. The computer-implemented method of claim 1, wherein the first selection of the first part is identified by the generative machine learning model based on the plurality of design constraints.

12. One or more non-transitory computer-readable storage media including instructions that, when executed by at least one processor, cause the at least one processor to perform steps for iteratively generating machine assemblies according to design constraints, the steps comprising:
receiving a plurality of design constraints that define properties of a machine assembly;
receiving a first selection of a first part via a user interface, the first part selected from a virtual parts inventory;
identifying, using a generative machine learning model, a second part from the virtual parts inventory, the second part connectable to the first part based on the plurality of design constraints and a second selection of a first location within the first part; and
displaying the first part and the second part in a user interface, wherein the first part and the second part comprise a first portion of the machine assembly.

13. The one or more non-transitory computer-readable storage media of claim 12, wherein the instructions, when executed by the at least one processor, further cause the at least one processor to perform steps comprising:
further comprising receiving a third selection of the second part in the user interface, wherein the second part is selected from the virtual parts inventory.

14. The one or more non-transitory computer-readable storage media of claim 12, wherein the second selection of the first location within the first part comprises a selection in the user interface of a selectable portion of the first part.

15. The one or more non-transitory computer-readable storage media of claim 12, wherein the instructions, when executed by the at least one processor, further cause the at least one processor to perform steps comprising:
generating, using the generative machine learning model, a remainder of the machine assembly based on the first part and the second part; and
displaying the remainder of the machine assembly in the user interface.

16. The one or more non-transitory computer-readable storage media of claim 12, wherein the instructions, when executed by the at least one processor, further cause the at least one processor to perform steps comprising:
receiving a fourth selection of a second portion of the first part in the user interface;
identifying, using the generative machine learning model, a third part from the virtual parts inventory connectable to the first part based on the fourth selection of the second portion of the first part; and
displaying the first part and the third part in the user interface without the second part, wherein the first part and the third part comprise a second portion of the machine assembly.

17. The one or more non-transitory computer-readable storage media of claim 12, wherein the instructions, when executed by the at least one processor, further cause the at least one processor to perform steps comprising saving, in a data store, the first portion of the machine assembly as a first design branch.

18. The one or more non-transitory computer-readable storage media of claim 17, wherein the instructions, when executed by the at least one processor, further cause the at least one processor to perform steps comprising generating a second design branch associated with the machine assembly, wherein the second design branch is associated with a second portion of the machine assembly that is different from the first portion of the machine assembly.

19. The one or more non-transitory computer-readable storage media of claim 12, wherein the instructions, when executed by the at least one processor, further cause the at least one processor to perform steps comprising generating at a plurality of textual tokens associated with plurality of design constraints and the first selection of the first part, the instructions further causing the at least one processor to at least provide the plurality of textual tokens to the generative machine learning model.

20. A system, comprising:
one or more memories storing instructions; and
one or more processors that are coupled to the one or more memories and, when executing the instructions, are configured to perform steps for iteratively generating machine assemblies according to design constraints, the steps comprising:
receiving a plurality of design constraints that define properties of a machine assembly;
receiving a first selection of a first part via a user interface, the first part selected from a virtual parts inventory;
identifying, using a generative machine learning model, a second part from the virtual parts inventory, the second part connectable to the first part based on the plurality of design constraints and a second selection of a first location within the first part; and
displaying the first part and the second part in a user interface, wherein the first part and the second part comprise a first portion of the machine assembly.
